(19) United States
(12) Patent Application Publication
(10) Pub. No.: US 2025/0372981 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/220,098

(22) Filed: May 28, 2025

(30) Foreign Application Priority Data
Jun. 4, 2024 (JP) 2024-090422

(51) Int. Cl. H02G 3/08; B60R 16/023; H01R 25/16; H05K 7/20

(52) U.S. Cl. CPC H02G 3/081; B60R 16/0239; H01R 25/161; H01R 25/165; H05K 7/2039; H01R 2201/26

(57) ABSTRACT

An electrical connection unit includes a base portion, a bus bar, an electronic component, and a heat conduction portion. The base portion has a flat surface portion having a plate shape or sheet shape. A first accommodation portion recessed in a thickness direction of the flat surface portion or penetrating the flat surface portion in the thickness direction is formed in the flat surface portion. The bus bar is held by the flat surface portion. The electronic component faces the base member and is electrically connected to the bus bar. The heat conduction portion is electrically insulated from the bus bar and the electronic component, and is held by the base member in a state of being accommodated in the first accommodation portion. The heat conduction portion has a thermal conductivity higher than that of the base member.

### BACKGROUND OF THE INVENTION

### Field of the Invention

Embodiments of the present invention relate to an electrical connection unit.

Priority is claimed on Japanese Patent Application No. 2024-090422 filed in Japan on Jun. 4, 2024, the content of which is incorporated herein by reference.

### Description of the Related Art

There is an electrical connection unit including a plurality of electronic components.

### PRIOR ART DOCUMENT

### Patent Document

Patent Document 1: Japanese Unexamined Patent Application, First Publication No. 2024-037492

### SUMMARY OF THE INVENTION

Incidentally, it is expected to improve a heat dissipation property of an electrical connection unit.

An embodiment provides an electrical connection unit capable of improving a heat dissipation property.

An electrical connection unit according to an embodiment includes a base portion, a bus bar, an electronic component, and a heat conduction portion. The base portion has a flat surface portion having a plate shape or sheet shape. A first accommodation portion recessed in a thickness direction of the flat surface portion or penetrating the flat surface portion in the thickness direction is formed in the flat surface portion. The bus bar is held by the flat surface portion. The electronic component faces the base member and is electrically connected to the bus bar. The heat conduction portion is electrically insulated from the bus bar and the electronic component, and is held by the base member in a state of being accommodated in the first accommodation portion. The heat conduction portion has a thermal conductivity higher than that of the base member.

According to one embodiment, it is possible to provide an electrical connection unit capable of improving a heat dissipation property.

### BRIEF DESCRIPTION OF THE DRAWINGS

FIG. 1 is a cross-sectional view illustrating an electrical connection unit of a first embodiment;

FIG. 2 is a perspective view for describing a main body of the first embodiment;

FIG. 3 is a perspective view for describing a subunit of the first embodiment;

FIG. 4 is a partially exploded perspective view of the subunit of the first embodiment;

FIG. 5 is a perspective view illustrating a routing board of the first embodiment;

FIG. 6 is a partially exploded perspective view of the routing board according to the first embodiment;

FIG. 7 is a cross-sectional view taken along line F7-F7 in FIG. 4;

FIG. 8 is a plan view illustrating the routing board of the first embodiment;

FIG. 9 is a partially exploded perspective view of the electrical connection unit of the first embodiment;

FIG. 10 is a bottom view illustrating the routing board of the first embodiment;

FIG. 11 is a cross-sectional view taken along line F11-F11 of the structure illustrated in FIG. 8.

FIG. 12 is a cross-sectional view of an electrical connection unit according to a second embodiment, corresponding to FIG. 11;

FIG. 13 is a bottom view of a routing board according to a third embodiment;

FIG. 14 is a cross-sectional view corresponding to F14-F14 in FIG. 13;

FIG. 15 is a cross-sectional view corresponding to FIG. 14 for a modification example of the third embodiment; and

FIG. 16 is a cross-sectional view corresponding to FIG. 14 for a modification example of the third embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the specific constitution described below does not limit an applicable scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. “Accommodation” is not limited to a case where the entire component is accommodated, and may include a case where only part of the component is accommodated. The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

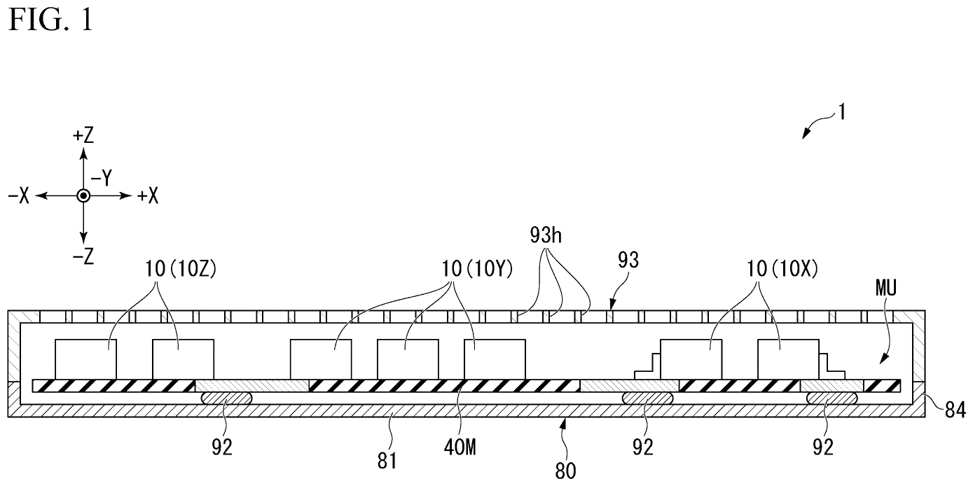

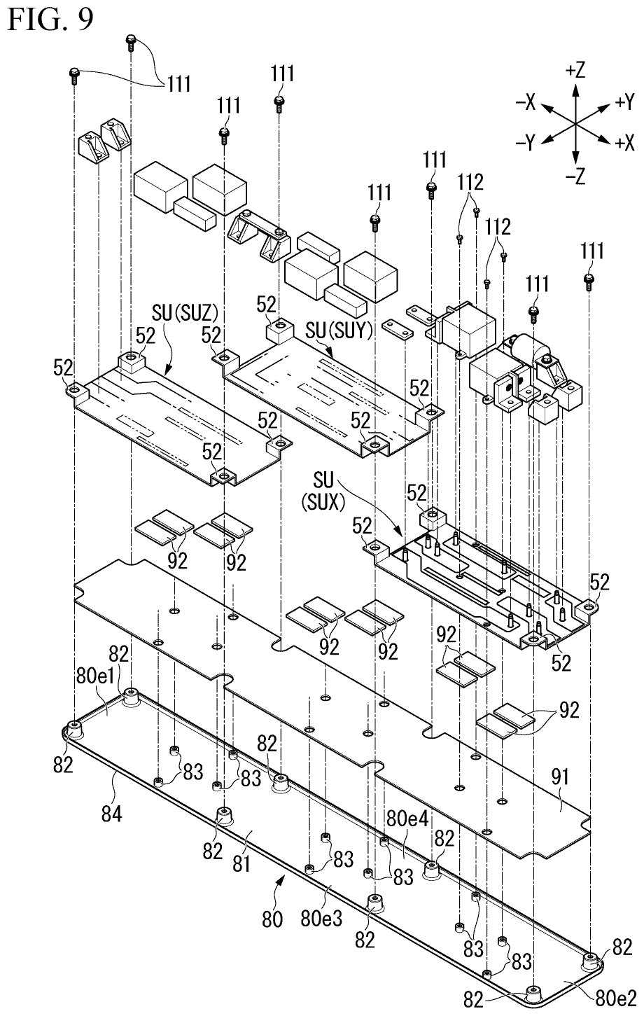

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 9). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 9). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “thickness direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### 1. Constitution of Electrical Connection Unit 1

FIG. 1 is a cross-sectional view illustrating an electrical connection unit 1 of an embodiment.

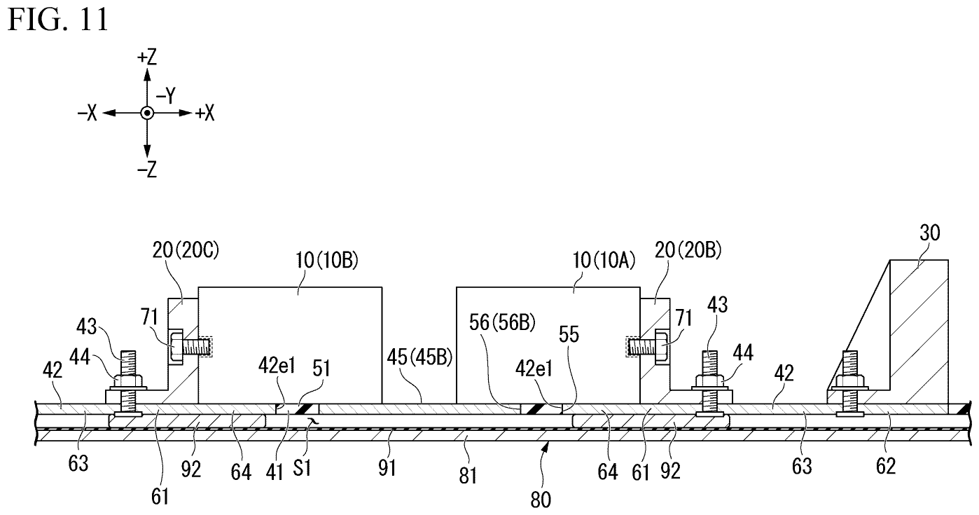

The electrical connection unit 1 illustrated in FIG. 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device. The electrical connection unit 1 includes, for example, a main body MU, a metal plate 80, an insulating sheet 91 (see FIG. 11), a plurality of heat transfer members 92, and an insulating cover 93.

### 2. Main Body MU

First, the main body MU will be described.

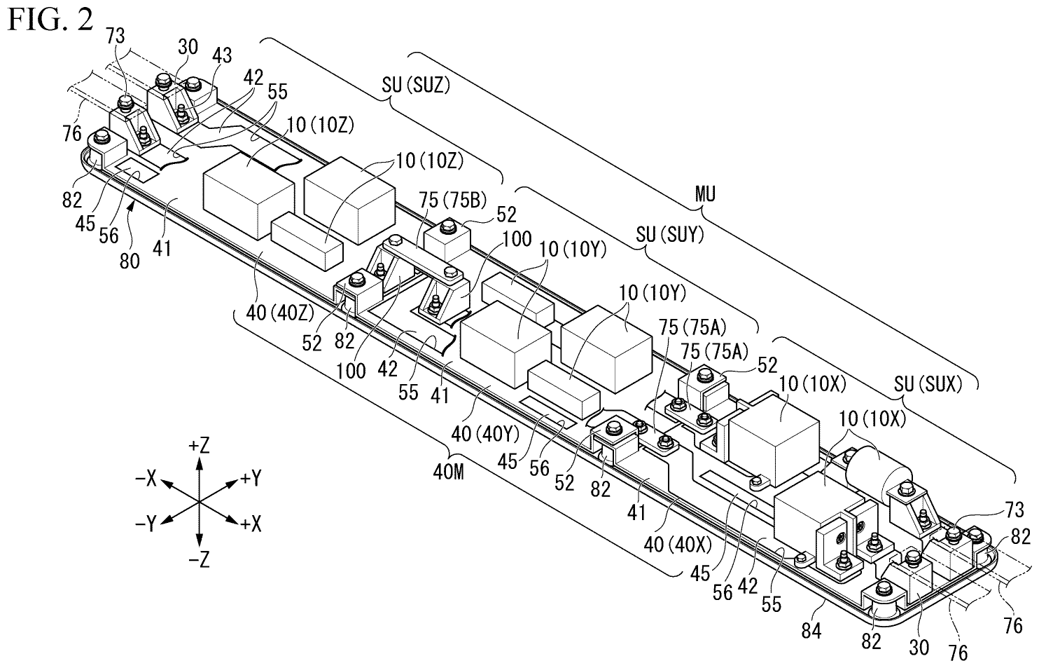

FIG. 2 is a perspective view for describing the main body MU.

The main body MU illustrated in FIG. 2 is a portion that performs a main function (for example, switching of electrical connection states or overcurrent protection) of the electrical connection unit 1. The main body MU is divided into, for example, a plurality of subunits SU. The main body MU is formed by, for example, connecting a plurality of subunits SU. In the present embodiment, the main body MU includes three subunits SU (first to third subunits SUX, SUY, and SUZ). Each subunit SU may be referred to as a “circuit constitution body”.

The first subunit SUX has a first electrical function. The first subunit SUX includes, for example, a plurality of electronic components 10X and a first routing board 40X. The plurality of electronic components 10X are electrically connected to the first routing board 40X.

The second subunit SUY has a second electrical function. The second function is a function different from the first function. The second subunit SUY includes, for example, a plurality of electronic components 10Y and a second routing board 40Y. The plurality of electronic components 10Y are electrically connected to the second routing board 40Y.

The third subunit SUZ has a third electrical function. The third function is a function different from the first function and the second function. The third subunit SUZ includes, for example, a plurality of electronic components 10Z and a third routing board 40Z. The plurality of electronic components 10Z are electrically connected to the third routing board 40Z.

In the present embodiment, the three subunits SUX, SUY, and SUZ are disposed to be arranged in the X direction. For example, the first subunit SUX is disposed on the +X direction side with respect to the second subunit SUY. The first subunit SUX and the second subunit SUY are electrically connected via a coupling bus bar 75 extending between the first routing board 40X and the second routing board 40Y. On the other hand, the third subunit SUZ is disposed on the −X direction side with respect to the second subunit SUY. The third subunit SUZ and the second subunit SUY are electrically connected via the coupling bus bar 75 extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. One large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the first subunit SUX, the second subunit SUY, and the third subunit SUZ are not distinguished, the subunits will be simply referred to as “subunit SU”. In a case where the electronic component 10X, the electronic component 10Y, and the electronic component 10Z are not distinguished, the electronic components will be simply referred to as “electronic component 10”. When the first routing board 40X, the second routing board 40Y, and the third routing board 40Z are not distinguished, the routing boards will be simply referred to as “routing board 40”.

### 3. Constitution of Subunit SU

Next, a constitution of the subunit SU will be described.

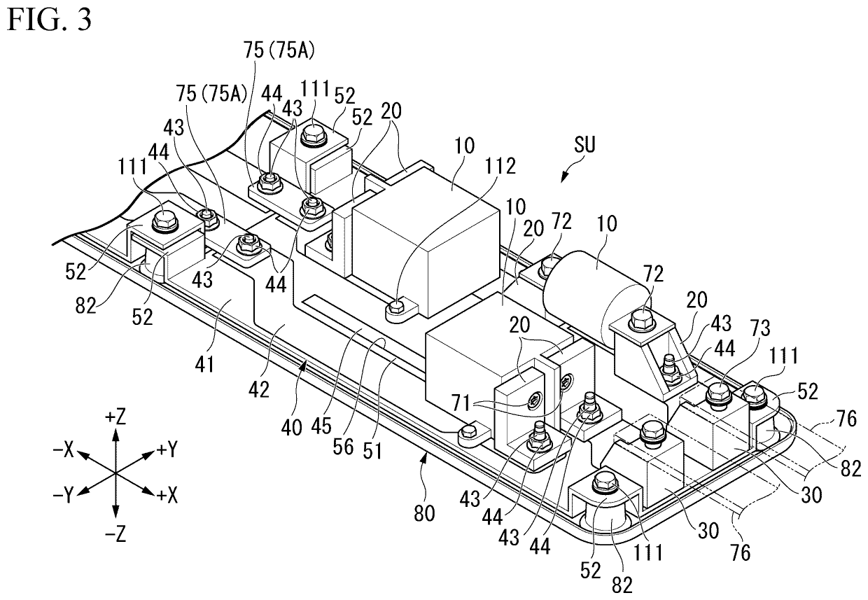

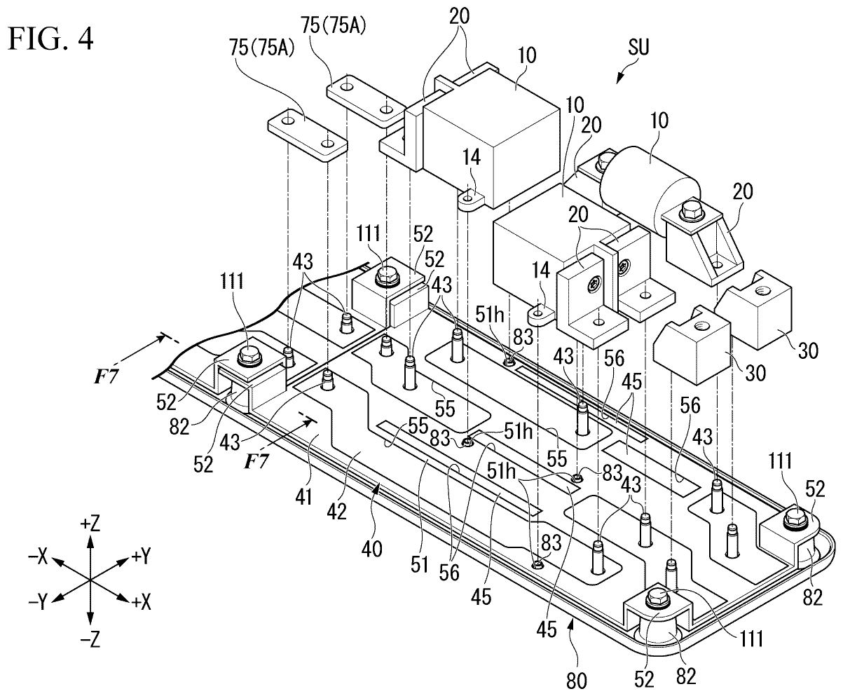

FIG. 3 is a perspective view for describing the subunit SU. FIG. 4 is a partially exploded perspective view of the subunit SU.

As illustrated in FIGS. 3 and 4, the subunit SU includes, for example, a plurality of electronic components 10, a plurality of connection components 20 for component connection, a plurality of connection components 30 for external connection, a routing board 40, a plurality of fastening members 71, 72, and 73, and a connection component 100 for unit connection (see FIG. 2).

### <3.1 Electronic Component 10 and Connection Component 20 for Component Connection>

First, the electronic component 10 and the connection component 20 will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization.

The connection component 20 is a component that electrically connects the electronic component 10 to the routing board 40. The connection component 20 forms part of an energization path in the subunit SU. The connection component 20 is made of a metal (for example, copper or a copper alloy). The connection component 20 is provided in a state of standing on the +Z direction side from the routing board 40. A first end (end on the −Z direction side) of the connection component 20 is connected to the bus bar 42 via a fastening member 43 (for example, a bolt). A second end (end on the +Z direction side) of the connection component 20 is connected to the electronic component 10 via a fastening member 71 (for example, a screw or a bolt).

### <3.2 Connection Component 30 for External Connection>

Next, the connection component 30 for external connection will be described.

The connection component 30 is a component that electrically connects the external connection bus bar 76 to the routing board 40. In the present embodiment, the connection component 30 electrically connects the external connection bus bar 76 to the bus bar 42 included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of a vehicle. However, the external device is not limited to a battery unit or an inverter.

Similarly to the connection component 20, the connection component 30 is made of a metal (for example, copper or a copper alloy). As illustrated in FIG. 2, the connection component 30 is provided in a state of standing on the +Z direction side at the outer peripheral portion (the end on the X direction side) of the routing board 40M. A first end (an end on the −Z direction side) of the connection component 30 is connected to the bus bar 42 via a fastening member 43 (for example, a bolt). A second end (an end on the +Z direction side) of the connection component 20 is connected to the external connection bus bar 76 via a fastening member 73 (for example, a screw or a bolt).

### <3.3 Connection Component 100 for Unit Connection>

Next, the connection component 100 for unit connection will be described.

As illustrated in FIG. 2, the connection component 100 electrically connects the adjacent subunits SU. In the present embodiment, the connection component 100 connects the bus bar 42 included in one subunit SU (for example, the second subunit SUY) to the bus bar 42 included in the other subunit SU (for example, the third subunit SUZ) among the adjacent subunits SU.

### <3.4 Routing Board 40>

First, the routing board 40 will be described.

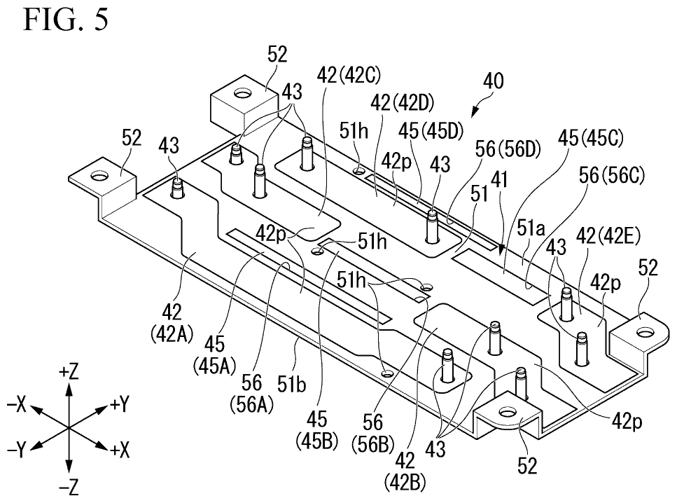

FIG. 5 is a perspective view illustrating the routing board 40.

As illustrated in FIG. 5, the routing board 40 is a member that forms at least part of an energization path between the plurality of electronic components 10 and/or at least part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41, one or more (for example, a plurality of) bus bars 42, a plurality of fastening members 43, and one or more (for example, a plurality of) heat conduction portions 45. In the present embodiment, the base plate 41, the plurality of bus bars 42, and the plurality of heat conduction portions 45 are integrated through insert molding. For example, the routing board 40 is formed as a single member by insert-molding the bus bar 42 and the heat conduction portion 45 with the base plate 41 after the fastening member 43 is fixed to the bus bar 42. That is, the bus bar 42 and the heat conduction portion 45 are integrated with the base plate 41 without using a fastening member such as a screw or a bolt. Note that the routing board 40 may be formed by another structure instead of the insert molding. In addition, one member of the bus bar 42 and the heat conduction portion 45 may be integrated with the base plate 41 through insert molding, and the other member may be provided on the base plate 41 by using a method different from the insert molding. The base plate 41 is an example of a “base member”.

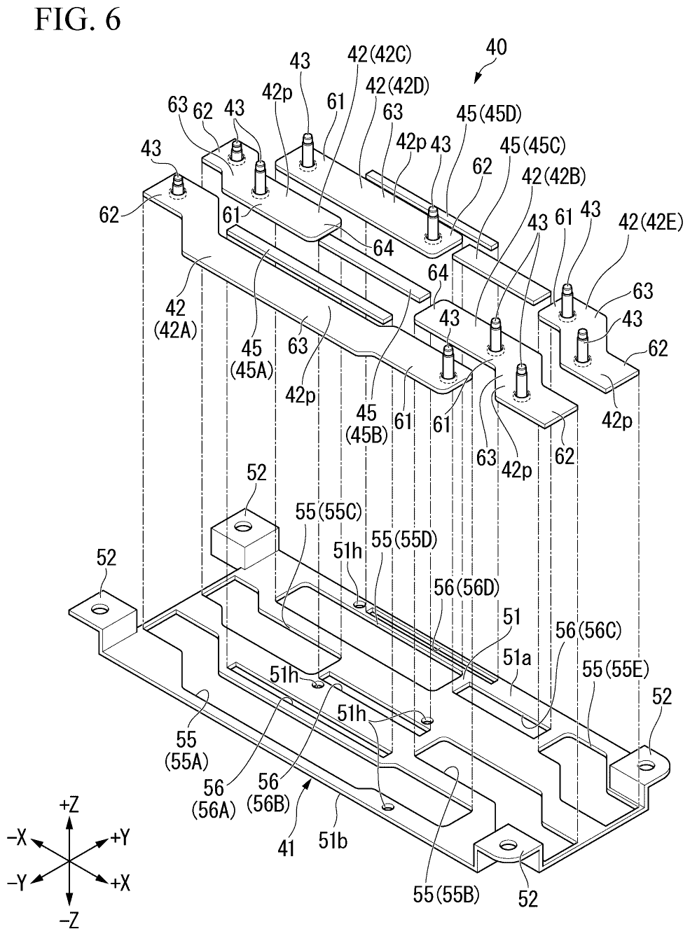

FIG. 6 is a partially exploded perspective view of the routing board 40. Hereinafter, for convenience of description, the base plate 41, the bus bars 42, and the fastening members 43 will be described with reference to the drawings in which the routing board 40 is partially exploded.

### (Base Plate 41)

As illustrated in FIG. 6, the base plate 41 is a holding member that integrally holds the plurality of bus bars 42 arranged in the horizontal direction at intervals. The base plate 41 is made of, for example, synthetic resin and has an insulating property. The base plate 41 is formed in, for example, a rectangular shape in which the X direction is a longitudinal direction and the Y direction is a lateral direction. The base plate 41 electrically insulates the plurality of bus bars 42 from each other. The base plate 41 includes, for example, a flat surface portion 51 and a plurality of fixing portions 52.

The flat surface portion 51 is a portion formed in a plate shape in the base plate 41. The flat surface portion 51 forms a main portion of the base plate 41. The flat surface portion 51 spreads in the horizontal direction. In the present embodiment, the flat surface portion 51 extends over the entire width in the X direction of the base plate 41 and over the entire width in the Y direction of the base plate 41 except for the four corner portions of the base plate 41.

The flat surface portion 51 has a first surface 51a and a second surface 51b. The first surface 51a is a surface directed toward the +Z direction side. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed toward the −Z direction side. The second surface 51b is a flat surface provided in the horizontal direction. The second surface 51b faces the metal plate 80 (see FIG. 1). A thickness direction (plate thickness direction) of the flat surface portion 51 is the Z direction.

In the flat surface portion 51, for example, one or more (for example, a plurality of) accommodation portions 55 in which the bus bars 42 are accommodated are formed. The plurality of accommodation portions 55 are formed apart from each other in the X direction or the Y direction. Each of the accommodation portions 55 is, for example, a through-hole penetrating the flat surface portion 51 in the Z direction. That is, each accommodation portion 55 is open in the Z direction on both the first surface 51a and the second surface 51b. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41). The accommodation portion 55 is an example of a “second accommodation portion”.

As illustrated in FIG. 6, each accommodation portion 55 is formed in an outer shape corresponding to the shape of the accommodated bus bar 42 when viewed from the Z direction. In the present embodiment, the flat surface portion 51 includes, for example, five accommodation portions 55A, 55B, 55C, 55D, and 55E as the plurality of accommodation portions 55.

In the flat surface portion 51, a through-hole 51h is formed at a position shifted in the X direction or the Y direction with respect to the accommodation portion 55. As illustrated in FIG. 4, the through-hole 51h is formed, for example, at a position overlapping the attachment portion 14 of the electronic component 10 when viewed from the Z direction. The attachment portion 14 is a portion for attaching the electronic component 10 to the metal plate 80. The attachment portion 14 protrudes in the X direction or the Y direction from a −Z direction-side end of the case of the electronic component 10.

One or more (for example, a plurality of) accommodation portions 56 in which the heat conduction portions 45 are accommodated are formed in the flat surface portion 51. The plurality of accommodation portions 56 are formed at positions shifted in the X direction or the Y direction with respect to the accommodation portion 55 of the bus bar 42 and the through-hole 51h in the flat surface portion 51. Each of the accommodation portions 56 is, for example, a through-hole penetrating the flat surface portion 51 in the Z direction. That is, each of the accommodation portions 56 is open in the Z direction on both the first surface 51a and the second surface 51b. Note that the accommodation portion 56 may be a recess provided on the first surface 51a or the second surface 51b of the flat surface portion 51 and recessed in the Z direction, instead of a through-hole.

Each of the accommodation portions 56 is formed in an outer shape corresponding to the shape of the accommodated heat conduction portion 45 when viewed from the Z direction. In the present embodiment, the flat surface portion 51 includes, for example, four accommodation portions 56A, 56B, 56C, and 56D as the plurality of accommodation portions 56.

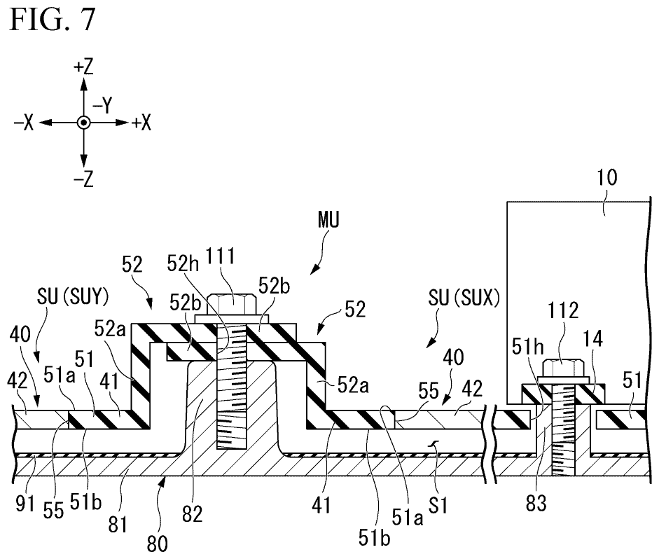

FIG. 7 is a cross-sectional view taken along line F7-F7 in FIG. 4.

As illustrated in FIGS. 4 and 7, the fixing portion 52 is a portion used for fixing the metal plate 80 and the base plate 41. The fixing portion 52 is provided at a corner portion of the base plate 41. The fixing portion 52 includes, for example, a standing plate portion 52a and a horizontal plate portion 52b.

The standing plate portion 52a stands on the +Z direction side from the end of the flat surface portion 51 of the base plate 41. The standing plate portion 52a is formed in, for example, an L shape when viewed from the Z direction. That is, the standing plate portion 52a extends in the Z direction in a state in which a part thereof in the horizontal direction is open.

The horizontal plate portion 52b extends in the horizontal direction from the end of the standing plate portion 52a on the +Z direction side. The horizontal plate portion 52b is a plate portion provided in the horizontal direction. The horizontal plate portion 52b extends in an eaves shape to cover a portion surrounded by the standing plate portion 52a from the +Z direction side.

### (Bus Bar 42)

As illustrated in FIGS. 5 and 6, the bus bar 42 is a routing member (electrical connection member) included in the routing board 40. The bus bar 42 is, for example, a routing member for electrically connecting the plurality of electronic components 10 to each other. The bus bar 42 may be a routing member for connecting one electronic component 10 to an external device. The bus bar 42 is made of a metal (for example, copper or a copper alloy) and has conductivity. In the present embodiment, the routing board 40 includes, for example, five bus bars 42A, 42B, 42C, 42D, 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E are held by the flat surface portion 51 of the base plate 41.

At least part of each bus bar 42 has a plate shape formed in the horizontal direction. At least part of each bus bar 42 extends along the flat surface portion 51 in a state of being accommodated in the accommodation portion 55. At least part of each bus bar 42 extends along the first surface 51a of the flat surface portion 51. At least part of each bus bar 42 extends in the horizontal direction in the accommodation portion 55. In the present embodiment, each bus bar 42 has a plate shape formed in the horizontal direction over the entire bus bar 42. Each of the bus bars 42 extends along the flat surface portion 51 in a state of being accommodated in the accommodation portion 55 over the entire length of the bus bar 42. Hereinafter, in each bus bar 42, a portion accommodated in the accommodation portion 55 (a portion extending along the flat surface portion 51) may be referred to as a “plate portion 42p”.

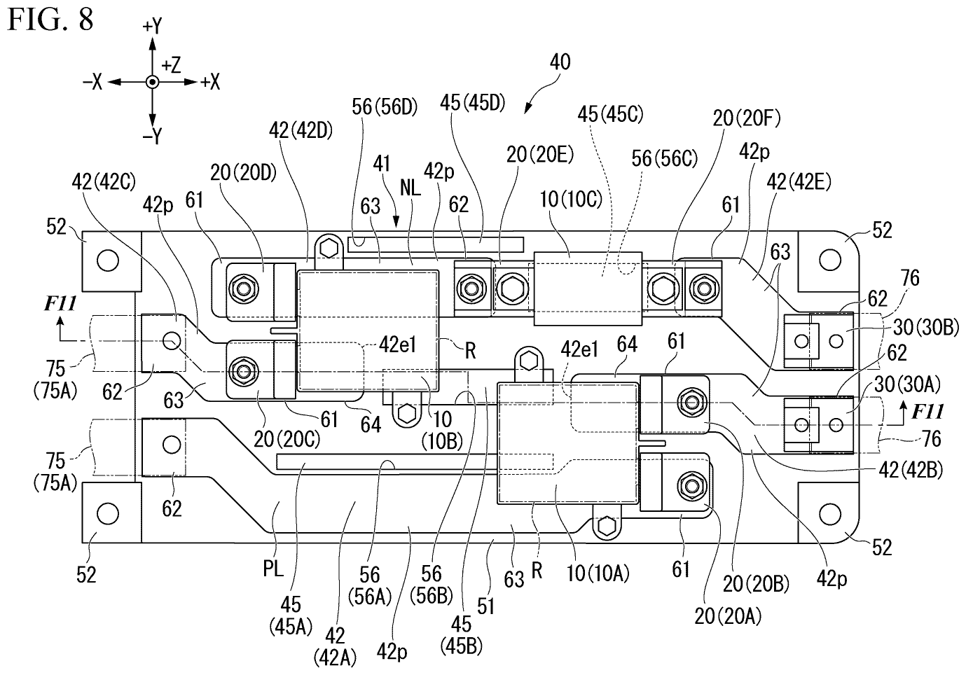

FIG. 8 is a plan view illustrating the routing board 40.

As illustrated in FIG. 8, the plate portion 42p of each bus bar 42 includes, for example, a first connection portion 61, a second connection portion 62, and an extending portion 63.

The first connection portion 61 is a portion in contact with one connection component 20 (hereinafter referred to as a “first connection component 20”) among the plurality of connection components 20. The first connection component 20 is a connection component that connects one electronic component 10 (hereinafter referred to as a “first electronic component 10”) among the plurality of electronic components 10 to the bus bar 42. The first connection portion 61 is a portion of the bus bar 42 overlapping the first connection component 20 when viewed from the Z direction. The first connection portion 61 is adjacent to the first connection component 20 in the Z direction. The first connection portion 61 is connected to the first connection component 20 from the Z direction.

The second connection portion 62 is a portion in contact with the connection component 20 (hereinafter referred to as a “second connection component 20”) different from the first connection component 20 among the plurality of connection components 20. The second connection component 20 is a connection component that connects the electronic component 10 (hereinafter referred to as a “second electronic component 10”) different from the first electronic component 10 among the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction. The second connection portion 62 is connected to the second connection component 20 from the Z direction.

The second connection portion 62 may be a portion in contact with the connection component 30. The connection component 30 is a connection component for connecting an external device to the bus bar 42. In this case, the second connection portion 62 is a portion of the bus bar 42 overlapping the connection component 30 when viewed from the Z direction. The second connection portion 62 is adjacent to the connection component 30 in the Z direction. The second connection portion 62 is connected to the connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction. The second connection portion 62 is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 extends along the flat surface portion 51 in a state of being accommodated in the accommodation portion 55 at least over the first connection portion 61 and the second connection portion 62. For example, the first connection portion 61, the second connection portion 62, and the extending portion 63 extend along the flat surface portion 51 in a state of being accommodated in the accommodation portion 55. A portion of each bus bar 42 accommodated in the accommodation portion 55 is exposed on the first surface 51a and the second surface 51b of the flat surface portion 51. That is, the surface of each bus bar 42 directed in the Z direction is exposed to the outside of the base plate 41 (for example, in the +Z direction and the −Z direction) through the opening of the accommodation portion 55. However, part of the bus bar 42 may be buried in the base plate 41.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends linearly in the X direction. The extending portion 63 extends over a region R overlapping the electronic component 10 when viewed from the Z direction, over the +X direction side and the −X direction side of the region R.

The one or more bus bars 42 may have an extension 64 in addition to the first connection portion 61, the second connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 extends along the flat surface portion 51 in a state of being accommodated in the accommodation portion 55. The extension 64 is accommodated in the accommodation portion 55 to extend to the region R overlapping the electronic component 10 when viewed from the Z direction. The extension 64 has an end 42e1 of the bus bar 42 at a position overlapping the region R when viewed from the Z direction.

Some routing examples of the bus bar 42 will be described below. The plurality of electronic components 10 include three electronic components 10A, 10B, and 10C. The plurality of connection components 20 include six connection components 20A, 20B, 20C, 20D, 20E, and 20F. The plurality of connection components 30 include two connection components 30A and 30B.

### First Routing Example

First, a routing example related to the bus bar 42A will be described.

The bus bar 42A includes a first connection portion 61, a second connection portion 62, and an extending portion 63. The first connection portion 61 is located on the +X direction side with respect to the electronic component 10A when viewed from the Z direction. The first connection portion 61 is electrically connected to, for example, a positive electrode terminal of the electronic component 10A via the connection component 20A. The second connection portion 62 is located on the −X direction side with respect to the electronic component 10A when viewed from the Z direction. The second connection portion 62 is electrically connected to another subunit SU via the coupling bus bar 75.

The extending portion 63 is accommodated in the accommodation portion 55 to extend over both sides of the region R through the region R overlapping the electronic component 10A when viewed from the Z direction. For example, the extending portion 63 extends linearly in the X direction. The extending portion 63 extends over the region R overlapping the electronic component 10A when viewed from the Z direction, over the +X direction side and the −X direction side of the region R. The bus bar 42A is, for example, a bus bar included in the positive electrode line PL included in the electrical connection unit 1.

### Second Routing Example

Next, a routing example related to the bus bar 42B will be described.

The bus bar 42B has a first connection portion 61, a second connection portion 62, an extending portion 63, and an extension 64. The first connection portion 61 is electrically connected to, for example, a negative electrode terminal of the electronic component 10A via the connection component 20B different from the first connection component 20. The second connection portion 62 is electrically connected to the external connection bus bar 76 via the connection component 30A. The extension 64 extends to the region R overlapping the electronic component 10A when viewed from the Z direction. The extension 64 has an end 42e1 of the bus bar 42 at a position overlapping the region R when viewed from the Z direction. Note that the extending portion 63 of the bus bar 42B may extend over both sides of the region R through the region R overlapping the electronic component 10 when viewed from the Z direction, similarly to the extending portion 63 of the bus bar 42A. The bus bar 42B is, for example, a bus bar included in the positive electrode line PL included in the electrical connection unit 1.

### Third Routing Example

Next, a routing example related to the bus bar 42C will be described.

The bus bar 42C includes a first connection portion 61, a second connection portion 62, an extending portion 63, and an extension 64. The first connection portion 61 is electrically connected to, for example, a negative electrode terminal of the electronic component 10B via the connection component 20C. The second connection portion 62 is electrically connected to another subunit SU via the coupling bus bar 75. The extension 64 extends to a region R overlapping the electronic component 10B when viewed from the Z direction. In the extension 64, the bus bar 42C having the end 42e1 of the bus bar 42 at a position overlapping the region R when viewed from the Z direction is, for example, a bus bar included in a negative electrode line NL of the electrical connection unit 1.

### Fourth Routing Example

Next, a routing example related to the bus bar 42D will be described.

The bus bar 42D has a first connection portion 61, a second connection portion 62, and an extending portion 63. The first connection portion 61 is electrically connected to, for example, a positive electrode terminal of the electronic component 10B via the connection component 20D. The second connection portion 62 is electrically connected to, for example, a negative electrode terminal of the electronic component 10C via the connection component 20E. The bus bar 42D is, for example, a bus bar included in the negative electrode line NL included in the electrical connection unit 1.

### Fifth Routing Example

Next, a routing example related to the bus bar 42E will be described.

The bus bar 42E includes a first connection portion 61, a second connection portion 62, and an extending portion 63. The first connection portion 61 is electrically connected to, for example, a negative electrode terminal of the electronic component 10C via the connection component 20F. The second connection portion 62 is electrically connected to the external connection bus bar 76 via the connection component 30B. The bus bar 42E is, for example, a bus bar included in the negative electrode line NL included in the electrical connection unit 1.

### (Fastening Member 43)

Next, referring to FIG. 6 again, the fastening member 43 will be described.

The fastening member 43 is a component for fixing the bus bar 42 and a connection target component (the connection component 20, the connection component 30, or the coupling bus bar 75) of the bus bar 42. The fastening member 43 is, for example, a caulking bolt fixed to the bus bar 42. The fastening member 43 penetrates the bus bar 42 in the Z direction. The fastening member 43 is electrically and physically connected to the bus bar 42 in a state of protruding toward the +Z direction side from the bus bar 42. Note that the fastening member 43 is not limited to caulking fixation and may be fixed to the bus bar 42 through welding or other methods.

The connection component 20 is fixed to the fastening member 43 while being previously fixed to the electronic component 10 via the fastening member 71 or the fastening member 72. For example, the fastening member 43 penetrates the first end of the connection component 20. As illustrated in FIG. 3, an engagement member 44 (for example, a nut) is attached to a portion of the fastening member 43 protruding toward the +Z direction side from the connection component 20. With this attachment, the connection component 20 is mounted on the routing board 40. In the present disclosure, the phrase “an electronic component is mounted on a board” is not limited to a case where the electronic component is directly connected to the board, and includes a case where the electronic component is connected to the board via another component (for example, the connection component 20). In the present disclosure, the phrase “an electronic component is mounted on a board” indicates that at least the electronic component is electrically connected to the board, and includes a case where the electronic component is fixed to a member (for example, the metal plate 80) different from the board instead of/in addition to the board.

### (Heat Conduction Portion 45)

As illustrated in FIGS. 5 and 6, the heat conduction portion 45 is a member for releasing and/or storing heat of the base plate 41 when the heat of the base plate 41 is transferred thereto. The heat conduction portion 45 is held by the flat surface portion 51 in a state of being electrically insulated from the bus bar 42. In the present embodiment, the heat conduction portion 45 is adjacent to the bus bar 42 while securing electrical insulation between the heat conduction portion 45 and the bus bar 42. The heat conduction portion 45 is made of a material having a thermal conductivity higher than that of the base plate 41. In the present embodiment, similarly to the bus bar 42, the heat conduction portion 45 is made of a metal (for example, copper or a copper alloy). The heat conduction portion 45 may overlap the electronic component 10 when viewed from the Z direction as long as the heat conduction portion 45 is electrically insulated from the electronic component 10.

The heat conduction portion 45 is formed in a plate shape in the horizontal direction. At least part of the heat conduction portion 45 extends along the flat surface portion 51 in a state of being accommodated in the accommodation portion 56. At least part of each of the heat conduction portions 45 extends along the first surface 51a of the flat surface portion 51. At least part of each of the heat conduction portions 45 extends in the horizontal direction in the accommodation portion 56. In the present embodiment, each of the heat conduction portions 45 extends along the flat surface portion 51 in a state of being accommodated in the accommodation portion 56 over the entire heat conduction portion 45. However, at least part of the heat conduction portion 45 may be accommodated in the accommodation portion 56. The heat conduction portion 45 may extend in the extending direction of the bus bar 42 in the horizontal direction, or may extend in a direction intersecting the extending direction of the bus bar 42. The heat conduction portion 45 may be formed in a block shape. In the present disclosure, the “block shape” is a shape in which the dimensions in the X direction and the Y direction are equal to the dimension in the Z direction.

The heat conduction portion 45 is disposed on the same plane as the bus bar 42. That is, at least part of the heat conduction portion 45 is disposed within a dimension range of the bus bar 42 in the Z direction. However, the heat conduction portion 45 and the bus bar 42 may be disposed at positions shifted from each other in the Z direction. The width (a dimension in the direction orthogonal to the extending direction) of the heat conduction portion 45 is smaller than the width of the bus bar 42. However, the width of the heat conduction portion 45 may be larger than the width of the bus bar 42.

The heat conduction portions 45 include, for example, heat conduction portions 45A, 45B, 45C, and 45D. The heat conduction portions 45A, 45B, 45C, and 45D are disposed at intervals in the horizontal direction.

The heat conduction portion 45A is accommodated in the accommodation portion 56A. The heat conduction portion 45A extends linearly in the X direction along the extending portion 63 on the +Y direction side with respect to the bus bar 42A. In the illustrated example, the heat conduction portion 45A overlaps at least part of the first connection portion 61 and the second connection portion 62 when viewed from the X direction.

The heat conduction portion 45B is accommodated in the accommodation portion 56B. The heat conduction portion 45B extends linearly in the X direction in a portion of the flat surface portion 51 located between the bus bar 42B and the bus bar 42C. In the illustrated example, the width of the heat conduction portion 45B is larger than the width of the heat conduction portion 45A.

The heat conduction portion 45C is accommodated in the accommodation portion 56C. The heat conduction portion 45C extends linearly in the X direction in a portion of the flat surface portion 51 located between the bus bar 42D and the bus bar 42E.

The heat conduction portion 45D extends linearly in the X direction on the +Y direction side with respect to the bus bar 42D. That is, the heat conduction portion 45A is provided on the outermost peripheral portion of the flat surface portion 51 on the +Y direction side. In this case, the heat conduction portion 45A may be exposed on the outer peripheral surface of the flat surface portion 51. Note that an installation position of the heat conduction portion 45 can be set at any position of the base plate 41 as long as the heat conduction portion 45 is electrically insulated from the bus bar 42.

### 4. Connection Structure

Next, a connection structure of the subunit SU will be described.

As illustrated in FIG. 2, the first subunit SUX, the second subunit SUY, and the third subunit SUZ are arranged in this order from the +X direction side to the −X direction side. The first subunit SUX and the second subunit SUY are electrically connected via a coupling bus bar 75A. The second subunit SUY and the third subunit SUZ are electrically and physically connected via a coupling bus bar 75B.

The adjacent subunits SU are disposed in a state in which the ends facing each other in the X direction overlap each other in the Z direction. Specifically, the fixing portion 52 (horizontal plate portion 52b) located on the +X direction side in the second subunit SUY overlaps the fixing portion 52 (horizontal plate portion 52b) located on the −X direction side in the first subunit SUX from the +Z direction side. The fixing portion 52 (horizontal plate portion 52b) located on the −X direction side in the second subunit SUY overlaps the fixing portion 52 (horizontal plate portion 52b) located on the +X direction side in the third subunit SUX from the +Z direction side.

### 5. Metal Plate 80, Insulating Sheet 91, Heat Transfer Member 92, and Insulating Cover 93

Next, the metal plate 80, the insulating sheet 91, the heat transfer member 92, and the insulating cover 93 will be described.

### <5.1 Metal Plate 80>

FIG. 9 is a partially exploded perspective view of the electrical connection unit 1.

As illustrated in FIG. 9, the metal plate 80 is a member for securing a rigidity of the electrical connection unit 1 and enhancing a heat dissipation property of the electrical connection unit 1. The metal plate 80 is made of a metal (for example, aluminum or an aluminum alloy). The metal plate 80 is an example of a “heat dissipation plate”. The heat dissipation plate is not limited to a metal, and various materials can be applied as long as the heat dissipation plate is made of a material superior in thermal conductivity to the base plate 41, for example.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. In the present embodiment, the metal plate 80 has a size that covers the entire three subunits SU (main body MU) from below. Specifically, the length of the metal plate 80 in the X direction is larger than the length of the main body MU in the X direction. The length of the metal plate 80 in the Y direction is larger than the length of the main body MU in the Y direction. Therefore, when viewed from the Z direction, the area of the metal plate 80 is larger than the area of the main body MU.

The metal plate 80 includes, for example, a flat surface portion 81, a plurality of fixing portions 82, a plurality of fixing portions 83, and a peripheral wall portion 84.

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the entire three subunits SU (main body MU) from below. The flat surface portion 81 faces the routing boards 40 of the three subunits SU. In the present embodiment, the metal plate 80 faces the second surface 51b of each subunit SU with a gap S1 (see FIG. 7) between the metal plate 80 and the flat surface portion 51 (second surface 51b) of each subunit SU.

As illustrated in FIGS. 7 and 9, the fixing portion 82 is a portion for fixing the base plate 41 of each subunit SU to the metal plate 80. The fixing portion 82 is provided at a position corresponding to the fixing portion 52 of each subunit SU when viewed from the Z direction. The fixing portion 82 is a cylindrical or prismatic boss protruding in the +Z direction from the flat surface portion 81 of the metal plate 80.

The fixing portion 83 is a portion for directly fixing the electronic component 10 of each subunit SU to the metal plate 80 without using the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The amount of protrusion of the fixing portion 83 in the Z direction is smaller than the amount of protrusion of the fixing portion 82 in the Z direction.

As illustrated in FIG. 2, the peripheral wall portion 84 extends from the outer peripheral edge of the flat surface portion 81 toward the +Z direction side. The peripheral wall portion 84 extends over the entire periphery of the flat surface portion 81. The length of the peripheral wall portion 84 in the Z direction is shorter than the lengths of the fixing portions 82 and 83 in the Z direction.

### <5.2 Insulating Sheet 91>

The insulating sheet 91 is an insulating member for electrically insulating the metal plate 80 and the bus bars 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 is provided to cover the entire flat surface portion 81 of the metal plate 80 from the +Z direction side. Therefore, the main body MU faces the metal plate 80 with the insulating sheet 91 interposed therebetween.

The insulating sheet 91 is attached to the flat surface portion 81 of the metal plate 80. A notch or an opening for avoiding the fixing portion 82 and the fixing portion 83 of the metal plate 80 is formed in the insulating sheet 91. In the present embodiment, the thickness of the insulating sheet 91 in the Z direction is smaller than the thickness of the peripheral wall portion 84 in the Z direction. Therefore, the insulating sheet 91 is positioned in the horizontal direction with respect to the metal plate 80 by being surrounded by the peripheral wall portion 84.

### <5.3 Heat Transfer Member 92>

As illustrated in FIG. 9, the heat transfer member 92 is a member for transferring heat generated by the electronic component 10 at the time of energization and/or heat generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

The plurality of heat transfer members 92 include, for example, one or more (for example, a plurality of) heat transfer members 92 corresponding to the first subunit SUX, one or more (for example, a plurality of) heat transfer members 92 corresponding to the second subunit SUY, and one or more (for example, a plurality of) heat transfer members 92 corresponding to the third subunit SUZ. The heat transfer member 92 corresponding to the first subunit SUX is disposed at a position overlapping the first subunit SUX when viewed from the Z direction, and transfers heat generated by the first subunit SUX to the metal plate 80. The heat transfer member 92 corresponding to the second subunit SUY is disposed at a position overlapping the second subunit SUY when viewed from the Z direction, and transfers heat generated by the second subunit SUY to the metal plate 80. The heat transfer member 92 corresponding to the third subunit SUZ is disposed at a position overlapping the third subunit SUZ when viewed from the Z direction, and transfers heat generated by the third subunit SUZ to the metal plate 80.

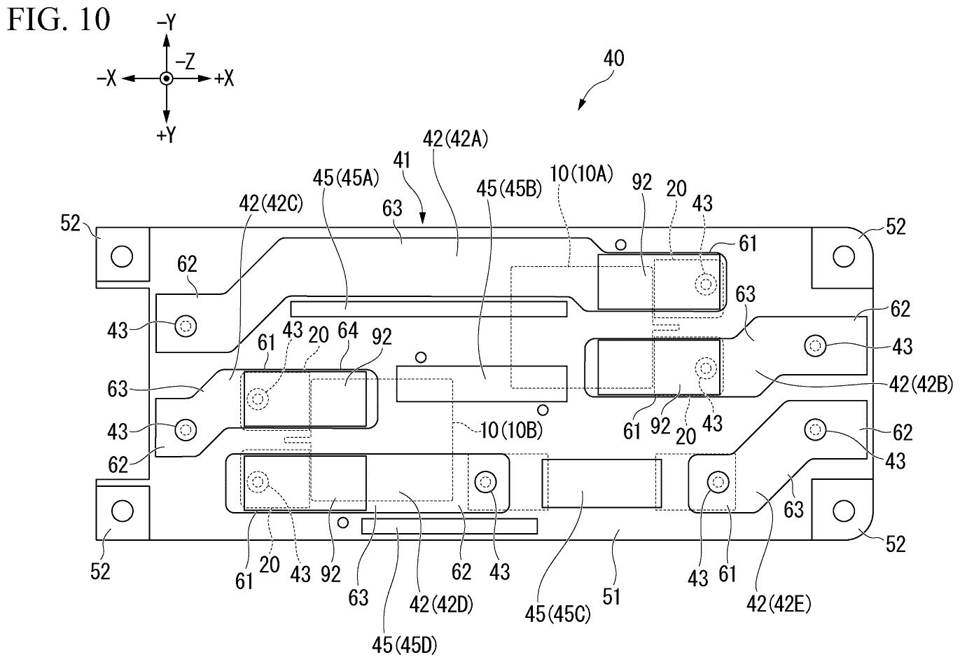

FIG. 10 is a bottom view illustrating the routing board 40.

As illustrated in FIG. 10, the heat transfer member 92 transfers heat transferred from the electronic component 10 to the bus bar 42 and/or heat generated in the bus bar 42 from the bus bar 42 to the metal plate 80. The plurality of heat transfer members 92 are partially provided in the routing board 40 in the horizontal direction. For example, the plurality of heat transfer members 92 are disposed at positions overlapping part of the bus bar 42 in the routing board 40 when viewed from the Z direction. The plurality of heat transfer members 92 are disposed at positions overlapping part of bus bar 42 in the vicinity of electronic components 10 (for example, the electronic components 10A and 10B) when viewed from the Z direction. In the present embodiment, the plurality of heat transfer members 92 are disposed at positions overlapping the connection component 20 (a connection portion between the bus bar 42 and the electronic component 10) when viewed from the Z direction.

FIG. 11 is a cross-sectional view taken along line F11-F11 of the structure illustrated in FIG. 8.

As illustrated in FIG. 11, the heat transfer member 92 is provided in a crushed state between the main body MU and the insulating sheet 91 in the Z direction. A portion of the heat transfer member 92 located on the −Z direction side is in contact with the metal plate 80 via the insulating sheet 91. The heat transfer member 92 may be provided between the insulating sheet 91 and the metal plate 80.

A portion of the heat transfer member 92 located on the +Z direction side is in contact with the bus bar 42. In the present embodiment, the heat transfer member 92 is in contact with the bus bar 42 at a position overlapping the connection component 20 when viewed from the Z direction. In this case, the heat transfer member 92 easily transfers the heat transferred from the electronic component 10 to the connection component 20 from the connection component 20 to the metal plate 80 via the bus bar 42. Part of the heat transfer member 92 is disposed at a position overlapping the fastening member 43 when viewed from the Z direction, and is in contact with the fastening member 43. In this case, the heat transfer member 92 easily transfers the heat transferred from the electronic component 10 to the connection component 20 from the fastening member 43 to the metal plate 80.

In the present embodiment, part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 11, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64.

### <5.4 Insulating Cover 93>

Referring to FIG. 1 again, the insulating cover 93 will be described. The insulating cover 93 is a member for securing safety of the main body MU with respect to the energization path. The insulating cover 93 is made of, for example, a synthetic resin and has an insulating property. The insulating cover 93 has, for example, a box shape that is open on the −Z direction side. The insulating cover 93 is attached to the metal plate 80 to cover the main body MU from the +Z direction side. In the present embodiment, a plurality of vent holes 93h are formed in the top wall of the insulating cover 93. Note that the insulating cover 93 is not limited to a box-shaped member, and may be a sheet-shaped member that covers the energization path of the main body MU.

### 6. Fixing Structure

Next, a fixing structure of the subunit SU will be described.

As illustrated in FIG. 7, the main body MU is stacked on the metal plate 80 in the Z direction in a state in which the fixing portions 52 of the adjacent subunits SU overlap the fixing portion 82 of the metal plate 80. The fixing portions 52 and 82 overlapping each other in the Z direction are fixed to each other via the fastening member 111 (for example, a screw or a bolt). The fastening member 111 penetrates the fixing portion 52 of the subunit SU and is then fastened to the fixing portion 82 of the metal plate 80.

In a state in which the main body MU and the metal plate 80 are stacked, the fixing portion 83 of the metal plate 80 penetrates the through-hole 51h of the subunit SU. The attachment portion 14 of the electronic component 10 overlaps the fixing portion 83 in the Z direction. The attachment portion 14 and the fixing portion 83 overlapping each other in the Z direction are fixed to each other via a fastening member 112 (for example, a screw or a bolt). The fastening member 112 penetrates the attachment portion 14 and is then fastened to the fixing portion 83 of the metal plate 80. A gap through which air can pass is provided between the inner circumferential surface of the through-hole 51h and the fixing portion 83.

### 7. Heat Transfer

As illustrated in FIG. 11, in the subunit SU, for example, heat is generated when the electronic component 10 is energized or when the bus bar 42 is energized. Part of the heat of the base plate 41 out of the heat generated in the subunit SU is transferred to the metal plate 80 (flat surface portion 81) via the heat transfer member 92 and the insulating sheet 91. Part of the heat of the base plate 41 is transferred to the fixing portion 82 of the metal plate 80 via the fixing portion 52. Further, part of the heat of the electronic component 10 is transmitted to the fixing portion 83 of the metal plate 80 via the attachment portion 14. As described above, the heat generated in the subunit SU is transferred to the metal plate 80 and then released from the metal plate 80 to the outside.

Here, part of the heat transferred to the base plate 41 is transferred to the heat conduction portion 45. The heat transferred to the heat conduction portion 45 is released from the heat conduction portion 45 to the outside. As described above, in the present embodiment, the heat transferred to the base plate 41 is transferred to the bus bars 42 and the heat conduction portions 45, so that the heat is easily diffused to the entire routing board 40. The heat diffused to the routing board 40 is directly released to the outside, or indirectly released to the outside via the heat transfer member 92 or the metal plate 80.

The electrical connection unit 1 of the present embodiment includes the base plate 41 having the flat surface portion 51 and having the accommodation portion 56 penetrating the flat surface portion 51 in the Z direction, the bus bar 42 held by the flat surface portion 51, the electronic component 10 facing the base plate 41 and electrically connected to the bus bar 42, and the heat conduction portion 45 electrically insulated from the bus bar 42 and the electronic component 10, held by the base plate 41 in a state of being accommodated in the accommodation portion 56, and having a thermal conductivity higher than that of the base plate 41.

According to this constitution, the heat transferred from an energization portion such as the bus bar 42 or the electronic component 10 to the base plate 41 can be effectively dissipated and/or stored in the heat conduction portion 45. With this constitution, the heat dissipation property of the electrical connection unit 1 can be improved. In addition, since the heat conduction portion 45 is accommodated in the accommodation portion 56, it is possible to reduce the height (thickness) of the electrical connection unit 1 compared with, for example, a case where the heat conduction portion 45 is provided on the first surface 51a or the second surface 51b of the flat surface portion 51 separately from the base plate 41. In addition, since the heat conduction portion 45 is accommodated in the accommodation portion 56, the base plate 41 and the heat conduction portion 45 can be easily handled integrally. With this constitution, handleability at the time of manufacturing the electrical connection unit 1 can be improved.

In the electrical connection unit 1 of the present embodiment, the heat conduction portion 45 extends in a direction intersecting the Z direction.

According to this constitution, the heat transferred to the heat conduction portion 45 can be diffused in the horizontal direction. With this constitution, the heat dissipation property can be improved.

In the electrical connection unit 1 of the present embodiment, the bus bar 42 is held by the base plate 41 in a state of being accommodated in the accommodation portion 55.

According to this constitution, since the bus bar 42 is accommodated in the accommodation portion 55, it is possible to reduce the height (thickness) of the electrical connection unit 1 compared with, for example, a case where the bus bar 42 is provided on the first surface 51a or the second surface 51b of the flat surface portion 51 separately from the base plate 41. Moreover, since the bus bar 42 is accommodated in the accommodation portion 55, the base plate 41 and the bus bar 42 can be easily handled integrally. With this constitution, handleability at the time of manufacturing the electrical connection unit 1 can be improved.

In the electrical connection unit 1 of the present embodiment, the bus bar 42 and the heat conduction portion 45 are insert-molded in the base plate 41.

According to this constitution, it is possible to eliminate or reduce the work of manually attaching the bus bars 42 and the heat conduction portions 45 to the base plate 41. With this constitution, it is possible to further improve the assemblability of the electrical connection unit 1.

In the electrical connection unit 1 of the present embodiment, at least part of the heat conduction portion 45 is exposed to the outside of the base plate 41 through the opening of the accommodation portion 56.

According to this constitution, the heat transferred to the heat conduction portion 45 is easily released to the outside. With this constitution, the heat dissipation property can be improved.

### 7. Second Embodiment

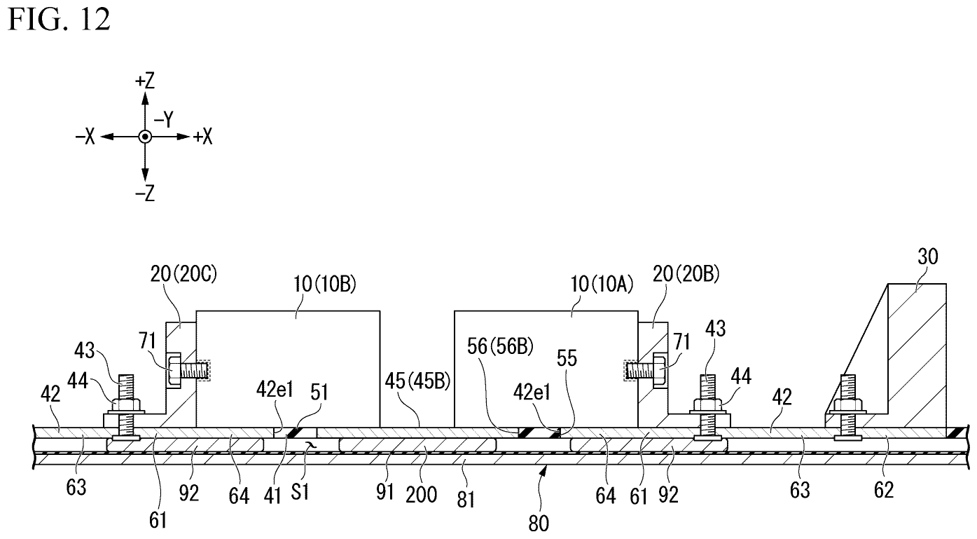

FIG. 12 is a cross-sectional view corresponding to FIG. 11 according to a second embodiment.

In the first embodiment described above, the constitution in which the heat transfer member 92 is disposed at the position overlapping the bus bar 42 when viewed from the Z direction has been described. However, as illustrated in FIG. 12, a heat transfer member 200 may be disposed at a position overlapping the heat conduction portion 45 when viewed from the Z direction. In this case, the heat transfer member 200 may overlap the entire heat conduction portion 45 or may overlap part of the heat conduction portion 45.

According to the present embodiment, the heat transferred to the heat conduction portion 45 is efficiently transferred to the metal plate 80 via the heat transfer member 200. Consequently, it is possible to further improve the heat dissipation property. As the heat transfer member 200, the same material as that of the heat transfer member 92 connected to the bus bar 42 can be used. However, since the heat conduction portion 45 does not function as an energization portion, a material having a conductivity may be used for the heat transfer member 200. The heat transfer members 92 and 200 may be integrally formed.

### 8. Third Embodiment

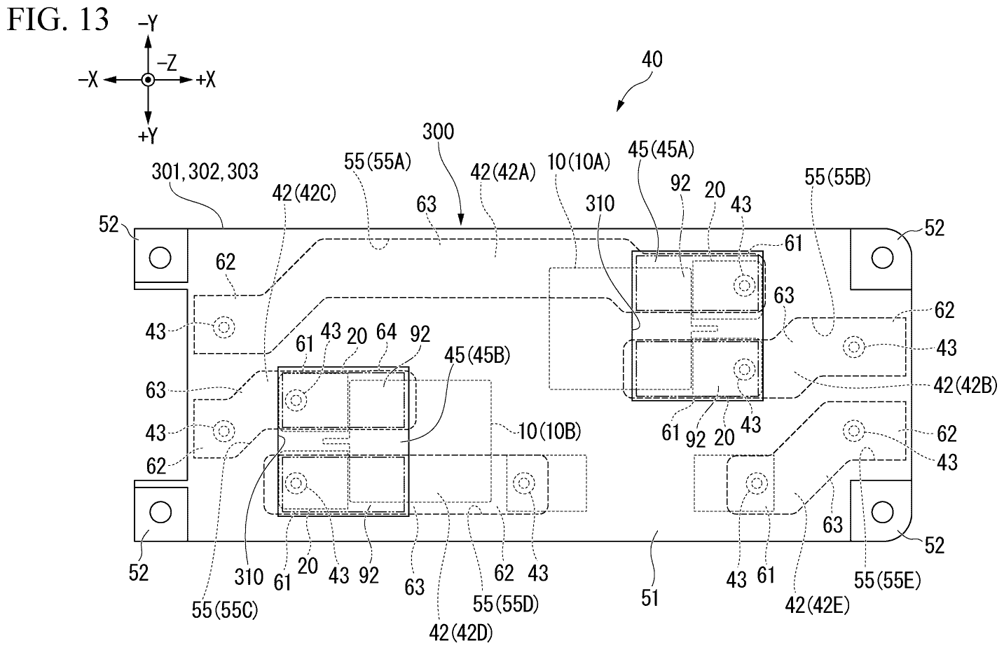

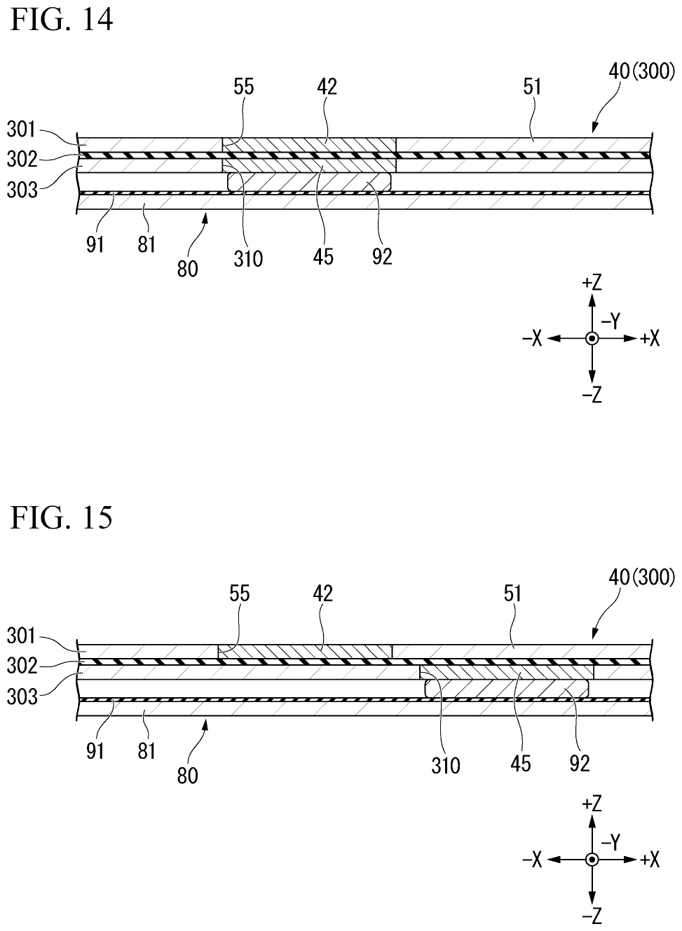

FIG. 13 is a bottom view of the routing board 40 according to a third embodiment. FIG. 14 is a cross-sectional view corresponding to F14-F14 in FIG. 13. The present embodiment is different from the above-described embodiments in that the base plate 41 has a two-layer structure.

In the routing board 40 illustrated in FIGS. 13 and 14, a base plate 300 includes a first plate 301, an insulating sheet 302, and a second plate 303. The first plate 301, the insulating sheet 302, and the second plate 303 are sequentially stacked from the +Z direction side to the −Z direction side. The first plate 301, the insulating sheet 302, and the second plate 303 are formed in the same outer shape when viewed from the Z direction. That is, the base plate 300 (the flat surface portion 51 and the fixing portion 52) is constituted by stacking the first plate 301, the insulating sheet 302, and the second plate 303. However, in the base plate 300, at least a portion located in the flat surface portion 51 may be formed by the first plate 301, the insulating sheet 302, and the second plate 303.

The first plate 301 is a plate that holds the bus bar 42. The first plate 301 and the bus bar 42 are integrated through insert molding. Of the first plate 301, a plurality of accommodation portions 55 are formed in a portion constituting the flat surface portion 51. Each of the accommodation portions 55 penetrates the first plate 301 in the Z direction. The bus bar 42 is accommodated in each of the accommodation portions 55.

The insulating sheet 302 electrically insulates the first plate 301 and the second plate 303 from each other. The insulating sheet 302 is interposed between the first plate 301 and the second plate 303. The insulating sheet 302 is fixed to a surface of the first plate 301 directed toward the −Z direction side and a surface of the second plate 303 directed toward the +Z direction side through, for example, adhesion. The insulating sheet 302 is made of, for example, a synthetic resin such as polyester or polyimide, and has an insulating property. The insulating sheet 302 covers the opening of the accommodation portion 55 on the −Z direction side to cover the bus bar 42 from the −Z direction side.

The second plate 303 is a plate that holds the heat conduction portion 45. The second plate 303 is fixed to the insulating sheet 302 through adhesion or the like. The second plate 303 and the heat conduction portion 45 are integrated through insert molding. Of the second plate 303, a plurality of accommodation portions 310 are formed in a portion constituting the flat surface portion 51. Each of the accommodation portions 310 penetrates the second plate 303 in the Z direction. The heat conduction portion 45 is accommodated in each of the accommodation portions 310. The heat conduction portions 45 are, for example, heat conduction portions 45A and 45B.

As illustrated in FIG. 13, the heat conduction portion 45A is provided at a position of the second plate 303 overlapping both of the first connection portions 61 of the bus bars 42A and 42B when viewed from the Z direction. In the present embodiment, the heat conduction portion 45A is formed in a rectangular shape having a direction (Y direction) intersecting an extending direction (X direction) of the first connection portion 61 in the bus bars 42A and 42B as a longitudinal direction when viewed from the Z direction. The heat conduction portion 45A is provided to straddle between the first connection portions 61 of the bus bars 42A and 42B when viewed from the Z direction.

The heat conduction portion 45A is exposed to both surfaces of the second plate 303 directed in the Z direction through the accommodation portion 310. The surface of the heat conduction portion 45A directed toward the +Z direction side faces the bus bars 42A and 42B in the Z direction via the insulating sheet 302. Heat conduction portion 45A and bus bars 42A, 42B are electrically insulated from each other via the insulating sheet 302. The surface of the heat conduction portion 45A directed toward the −Z direction side faces the metal plate 80 in the Z direction via the heat transfer member 92. The heat conduction portion 45A is thermally connected to the metal plate 80 via the heat transfer member 92.

The heat conduction portion 45B is provided at a position of the second plate 303 overlapping both of the first connection portions 61 of the bus bars 42C and 42D when viewed from the Z direction. In the present embodiment, the heat conduction portion 45B is formed in a rectangular shape having a direction (Y direction) intersecting the extending direction (X direction) of the first connection portion 61 in the bus bars 42C and 42D as a longitudinal direction when viewed from the Z direction. The heat conduction portion 45B is provided to straddle between the first connection portions 61 of the bus bars 42C and 42D when viewed from the Z direction.

Similarly to the heat conduction portion 45A, the heat conduction portion 45B is exposed to both surfaces of the second plate 303 directed in the Z direction through the accommodation portion 310. In this case, the surface of the heat conduction portion 45B directed toward the +Z direction side faces the bus bars 42C and 42D in the Z direction via the insulating sheet 302. The heat conduction portion 45B and the bus bars 42C and 42D are electrically insulated from each other via the insulating sheet 302. The surface of the heat conduction portion 45B directed toward the −Z direction side faces the metal plate 80 in the Z direction via the heat transfer member 92. The heat conduction portion 45B is thermally connected to the metal plate 80 via the heat transfer member 92.

According to the present embodiment, since the base plate 300 has a stacked structure of the first plate 301 holding the bus bar 42 and the second plate 303 holding the heat conduction portion 45, the bus bar 42 and the heat conduction portion 45 are disposed to be shifted in the Z direction. With this constitution, it is possible to improve the layout property between the bus bar 42 and the heat conduction portion 45, for example, by disposing the bus bar 42 and the heat conduction portion 45 in an overlapping manner when viewed from the Z direction.

In the present embodiment, since at least part of the bus bar 42 and the heat conduction portion 45 overlap each other when viewed from the Z direction, efficient heat transfer can be performed between the bus bar 42 and the heat conduction portion 45.

In the present embodiment, since the bus bar 42 (first connection portion 61) and the heat conduction portion 45 extend in directions intersecting each other when viewed from the Z direction, the degree of freedom of the heat transfer path can be improved.

In the third embodiment described above, the constitution in which at least part of the bus bar 42 and the heat conduction portion 45 overlap each other when viewed from the Z direction has been described, but the present invention is not limited to this constitution. For example, as illustrated in FIG. 15, the bus bar 42 and the heat conduction portion 45 may be disposed at positions shifted in the horizontal direction when viewed from the Z direction.

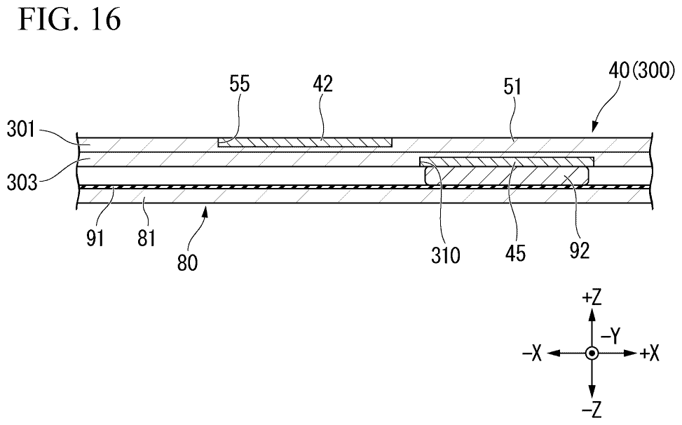

In the third embodiment described above, the constitution in which the insulating sheet 302 is interposed between the first plate 301 and the second plate 303 has been described, but as long as insulation between the bus bars 42 and the heat conduction portions 45 is achieved, the insulating sheet 302 is not an essential constitution as illustrated in FIG. 16. The insulation between the bus bar 42 and the heat conduction portion 45 can be achieved, for example, by forming at least one of the accommodation portions 55 and 310 as a recess that does not penetrate the plates 301 and 303. In addition, by disposing the bus bar 42 and the heat conduction portion 45 at positions shifted in the horizontal direction when viewed from the Z direction, insulation between the bus bar 42 and the heat conduction portion 45 can be achieved.

### 9. Other Modification Examples

Next, several modification examples will be described. Note that a constitution other than that described below in each modification example is the same as the constitution of the above embodiment.

### First Modification Example

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 by using an adhesive or other fixing means. In these cases, potting may be performed to fill a gap between the bus bar 42 and the accommodation portion 55.

### Second Modification Example

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The base plate 41 of the routing board 40 may include a plurality of members (plate members or sheet members). The plurality of members are provided to sandwich the plurality of bus bars 42 arranged in the horizontal direction, for example, from both sides in the Z direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of the bus bar 42 are exposed. For example, in this case, the accommodation portion 55 formed between the plurality of members corresponds to an example of an “accommodation portion recessed in the first direction (Z direction)”.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiments and the modification examples are not limited to the examples described above. For example, a plurality of embodiments may be implemented in combination with each other. The present invention is not limited by the above description, but only by the appended claims.

In the above-described embodiment, the electrical connection unit 1 for a vehicle has been described, but the present invention is not limited to this constitution.

In the above-described embodiment, the constitution in which the metal plate 80 is used as part of a casing of the main body MU has been described, but the present invention is not limited to this constitution. As the casing of the main body MU, a resin material or the like may be used. Even in this case, by using the heat conduction portion 45 having a heat dissipation/heat storage function in the base plate 41 as in the present embodiment, heat can be easily diffused throughout the base plate 41, and it is possible to curb heat from being confined in the electrical connection unit 1.

In the above-described embodiment, the constitution in which the routing board 40 and the bus bar 42 are integrally formed has been described, but the present invention is not limited to this constitution. The bus bar 42 may be formed separately from the routing board 40.

In the above-described embodiment, the constitution in which the bus bar 42 and the heat conduction portion 45 are made of the same material has been described, but the present invention is not limited to this constitution. The bus bar 42 and the heat conduction portion 45 may be made of different materials.

In the above-described embodiment, the constitution in which the bus bar 42 and the heat conduction portion 45 are formed to be flush with the base plate has been described, but the present invention is not limited to this constitution. The bus bar 42 and the heat conduction portion 45 may protrude from the base plate in the Z direction in a state of being accommodated in the corresponding accommodation portions.

In the above-described embodiment, the constitution in which the entire surface of the heat conduction portion 45 is exposed to the outside of the base plate through the accommodation portion has been described, but the present invention is not limited to this constitution. At least part of the heat conduction portion 45 may be exposed to the outside of the base plate.

In the above embodiment, an example in which the main body MU is constituted by the plurality of subunits SUX, SUY, and SUZ has been described, but the present invention is not limited to this constitution. The electrical connection unit 1 may be constituted by one circuit constitution body.

In the above-described embodiment, the constitution in which the heat conduction portion 45 is connected to the metal plate 80 via the heat transfer member has been described, but the present invention is not limited to this constitution. The heat conduction portion 45 may be directly connected to the metal plate 80.

In the above-described embodiment, the constitution in which the plurality of bus bars 42 and the plurality of heat conduction portions 45 are provided has been described, but the present invention is not limited to this constitution. The number of bus bars 42 and the number of heat conduction portions 45 may be one.

Although the embodiments of the present disclosure have been described and illustrated above, the embodiments are illustrated as examples and are not intended to limit the scope of the present disclosure. The above-described embodiments can be implemented in various other forms, and the constituents in the above-described embodiments can be replaced with well-known constituents, and various additions, omissions, substitutions, and changes can be made without departing from the concept of the present disclosure.

### INDUSTRIAL APPLICABILITY

According to the present disclosure, it is possible to provide an electrical connection unit capable of improving a heat dissipation property.

### REFERENCE SIGNS LIST

1 Electrical connection unit
10, 10A, 10B, 10C, 10X, 10Y, 10Z Electronic component
41 Base plate (base member)
42, 42A, 42B, 42C, 42D, 42E Bus bar
45, 45A, 45B, 45C, 45D Heat conduction portion
51 Flat surface portion
55, 55A, 55B, 55C, 55D, 55E Accommodation portion (second accommodation portion)
56, 56A, 56B, 56C, 56D Accommodation portion (first accommodation portion)
80 Metal plate (heat dissipation plate)
92, 200 Heat transfer member
300 Base plate (base member)
301 First plate
303 Second plate
310 Accommodation portion

What is claimed is:

1. An electrical connection unit comprising:
a base member having a flat surface portion having a plate shape or sheet shape, wherein a first accommodation portion recessed in a thickness direction of the flat surface portion or penetrating the flat surface portion in the thickness direction is formed in the flat surface portion;
a bus bar held by the flat surface portion;
an electronic component facing the base member and electrically connected to the bus bar; and
a heat conduction portion that is electrically insulated from the bus bar and the electronic component, is held by the base member in a state of being accommodated in the first accommodation portion, and has a thermal conductivity higher than a thermal conductivity of the base member.

2. The electrical connection unit according to claim 1, wherein
the heat conduction portion extends in a direction intersecting the thickness direction.

3. The electrical connection unit according to claim 1, wherein
a second accommodation portion recessed in the thickness direction or penetrating the flat surface portion in the thickness direction is formed at a position away from the first accommodation portion in the flat surface portion, and
the bus bar is held by the base member in a state of being accommodated in the second accommodation portion.

4. The electrical connection unit according to claim 1, wherein
the bus bar and the heat conduction portion are insert-molded in the base member.

5. The electrical connection unit according to claim 1, wherein
at least a part of the heat conduction portion is exposed to outside of the base member through an opening of the first accommodation portion.

6. The electrical connection unit according to claim 1, further comprising:
a heat dissipation plate provided to overlap the base member and thermally connected to the base member; and
a heat transfer member provided between the heat dissipation plate and the base member, wherein
the heat transfer member is provided at a position overlapping the heat conduction portion when viewed from the thickness direction.

7. The electrical connection unit according to claim 1, wherein
the base member includes
a first plate provided with the first accommodation portion and holding the heat conduction portion, and
a second plate stacked on the first plate in the thickness direction and holding the bus bar.

8. The electrical connection unit according to claim 7, wherein
the heat conduction portion is provided at a position overlapping at least a part of the bus bar when viewed in the thickness direction.

9. The electrical connection unit according to claim 7, wherein
the bus bar and the heat conduction portion extend in directions intersecting each other when viewed from the thickness direction.
